(19) United States
(12) Patent Application Publication
(10) Pub. No.: US 2010/0124090 A1
(43) Pub. Date: May 20, 2010

(54) SEMICONDUCTOR MEMORY DEVICE AND CONTROL METHOD THEREOF

(75) Inventor: Tetsuya ARAI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/620,771

(22) Filed: Nov. 18, 2009

(30) Foreign Application Priority Data
Nov. 18, 2008 (JP) 2008-294023

(51) Int. Cl. G11C 11/00; G11C 5/02

(52) U.S. Cl. 365/51; 365/163

(57) ABSTRACT

To provide data lines connected via column switches to a plurality of sense amplifiers and an input/output circuit that, in response to a write request, supplies pre-write data through the data line to selected phase change memory cells and then write data through the data line to the selected phase change memory cells. Thus, a pre-write operation and an actual write operation according to the write data can be performed at high speed. Because only the memory cells selected by a column address are subject to write, consumption power is reduced and lives of the memory cells are not shortened.

### BACKGROUND OF THE INVENTION

1. Field of the Invention

The present invention relates to a semiconductor memory device and a control method thereof, and more particularly relates to a semiconductor memory device having phase change memory cells and a control method thereof.

2. Description of Related Art

Recently, PRAM (Phase change Random Access Memory) has attracted attention as a non-volatile memory that realizes high speed access. The PRAM is configured by phase change memory cells including phase change materials and holds information based on the difference of an electric resistance depending on a phase state of the phase change material. Specifically, when the phase change material is in a crystalline state (a set state), relatively low resistance is provided, and when the phase change material is in an amorphous state (a reset state), relatively high resistance is provided. Accordingly, when the phase change material is either in the crystalline state or in the amorphous state, one bit of data (binary data) can be stored in one phase change memory cell. Such a change of phase state can be controlled by a waveform of a write current applied to the phase change memory cell.

However, the phase change material included in the phase change memory cell can be in an intermediate state in which the crystalline state and the amorphous state exist in a mixed manner. In this case, data held by the phase change memory cell is difficult to be determined, and this can be a cause of errors. That is, in an ordinary PRAM that stores one bit of data in one phase change memory cell, the intermediate state of the phase change material has to be eliminated. To store two or more bits (multi-bit) of data in one phase change memory cell, accurate control is required so that the phase change material is in a desired intermediate state.

To perform such elimination or control of an intermediate state, when data is written in a phase change memory cell, two-stage write is preferably performed. That is, a phase change material is temporarily made to be in a crystalline state or an amorphous state by a pre-write operation and then write data is written (see Japanese Patent Application Laid-open No. 2007-18681 and Japanese Patent Application National Publication No. 2005-536828).

When a pre-write operation is performed before an actual write operation, however, the time required for a sequence of such write operations is extended. Accordingly, high speed access becomes difficult to achieve, and the PRAM in this case cannot have a compatibility with a DRAM (Dynamic Random Access Memory), for example. Examples of a PRAM having a compatibility with a DRAM include a PRAM described in Japanese Patent Application Laid-open No. 2006-302465. According to the PRAM described in Japanese Patent Application Laid-open No. 2006-302465, in response to an active command (ACT), memory cells corresponding to a selected word'line are temporarily made to be in a set state (a pre-write operation) and then in response to an issuance of a precharge command (PRE), predetermined memory cells are reset, so that a high-speed access cycle is achieved.

However, because the PRAM described in Japanese Patent Application Laid-open No. 2006-302465 performs a set operation (a pre-write operation) upon all memory cells corresponding to the selected word line, power consumption therefore is increased. Also in a reset operation in response to a PRE command, when the number of memory cells to be reset is large, the power consumption is increased accordingly. Further, as the pre-write operation is performed in response to an ACT command, the pre-write operation and the write operation are performed during a read operation, and this causes the life of the memory cell to be shortened. Therefore, there has been a demand for a PRAM that can realize high speed access while being capable of eliminating or controlling an intermediate state in a pre-write operation.

### SUMMARY

The present invention seeks to solve one or more of the above problems, or to improve upon those problems at least in part.

In one embodiment, there is provided a semiconductor memory device comprising: a memory cell array including a plurality of word lines, a plurality of bit lines, a plurality of phase change memory cells arranged at intersections of the word lines with the bit lines, a plurality of sense amplifiers connected to corresponding bit lines, and a first column switch and a second column switch assigned to each of the sense amplifiers; a first data line and a second data line connected through the first column switches and the second column switches to the sense amplifiers, respectively; and an input/output circuit that supplies a pre-write data through the first data line to a selected phase change memory cell and then supplies a write data through the second data line to the selected phase change memory cell in response to a write request.

In another embodiment, there is also provided a control method of a semiconductor memory device including phase change memory cells, the control method comprising: performing a pre-write operation upon a selected phase change memory cell corresponding to a write address including a row address and a column address in response to an issuance of a write request; and performing a write operation upon the selected phase change memory cell that has been subjected to the pre-write operation according to a write data.

According to the present invention, each sense amplifier is connected through two data lines to an input/output circuit. Accordingly, a pre-write operation and an actual write operation according to write data can be performed at high speed. Further, because only memory cells selected by a column address are subjected to write, consumption power is reduced and lives of memory cells are not shortened.

As the present invention is applied to an ordinary PRAM that stores one bit of data in one phase change memory cell while ensuring high speed access, an intermediate state of a phase change material can be properly eliminated. As the present invention is applied to a multi-bit PRAM that stores two or more bits of data in one phase change memory cell, accurate control can be realized so that the phase change material is in a desired intermediate state.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram showing a configuration of principal parts of a semiconductor memory device 700 according to a first embodiment of the present invention;

FIG. 2 is a circuit diagram of a detection circuit 730;

FIG. 3 is a timing diagram showing an operation timing when the write operation is successively requested for different addresses (write-to-write operation) according to the first embodiment;

FIG. 4 is a timing diagram showing an operation timing when the write operation is successively requested for the same address (write-to-write operation) according to the first embodiment;

FIG. 5 is a timing diagram showing the write-to-write-to-read operation for the same address according to the first embodiment;

FIG. 6 is a circuit diagram of a detection circuit 730a;

FIG. 7 is a timing diagram showing the write-to-write-to-read operation for the same address according to the second embodiment;

FIGS. 8A, 8B, and 8C are explanatory diagrams of operation timings in the third embodiment, where FIG. 8A shows a single write operation, FIG. 8B shows a write-to-read operation, and FIG. 8C shows a write-to-write operation;

FIG. 9 is a circuit diagram of a detection circuit 730b;

FIG. 10 shows a circuit configuration obtained by deleting the circuit that handles the write-to-read from the semiconductor memory device 700;

FIG. 11 is a waveform diagram showing a pulse waveform when writing data to a PRAM memory cell;

FIG. 12 is a waveform diagram showing one example of a pulse waveform when writing multi-bit data to a PRAM memory cell;

FIG. 13 is a waveform diagram showing another example of a pulse waveform when writing multi-bit data to a PRAM memory cell;

FIG. 14 is a waveform diagram showing still another example of a pulse waveform when writing multi-bit data to a PRAM memory cell;

FIG. 15 is a waveform diagram showing still another example of a pulse waveform when writing multi-bit data to a PRAM memory cell;

FIG. 16 is a waveform diagram showing still another example of a pulse waveform when writing multi-bit data to a PRAM memory cell;

FIG. 17 is a circuit diagram showing a configuration of principal parts of a semiconductor memory device 900 according to the fourth embodiment;

FIG. 18A shows one mat array configuration;

FIG. 18B shows plural mat arrays configuration having a hierarchical data line configuration; and

FIG. 18C shows a configuration divided into plural banks.

### DETAILED DESCRIPTION OF THE EMBODIMENTS

Preferred embodiments of the present invention will be explained below in detail with reference to the accompanying drawings.

The PRAM is a semiconductor memory device using phase change materials for memory cells and stores information in a non-volatile manner depending on whether the phase change material is in a crystalline state (a set state) or in an amorphous state (a reset state). When the phase change material is controlled precisely so as to be in the intermediate state between the crystalline state and the amorphous state, more than binary of information can be recorded in a memory cell. Because such a multi-bit PRAM requires the control of the phase change material with high precision, it is desirable in any data writes that reset write (amorphizing) is performed once and set write (crystallizing) is then performed.

When such control is performed, in response to one write request, a write operation has to be performed twice. Accordingly, a second write operation according to a first write request collides with a read operation in the next cycle during a write-to-read operation. Also in a write-to-write operation, a second write operation according to a first write request collides with a first write operation in the next cycle. The present embodiment is to solve these problems. That is, the present embodiment handles the write-to-write operation in addition to measures for the write-to-read operation. Specifically, a memory cell array is connected to an input/output circuit by two data lines. One of the data lines is an I/O line and the other is a data line for write. The I/O line is used for a read path. For a write path, the I/O line is used during the first write operation and the data line for write is used during the second write operation. As a result, the problems of the write-to-read operation and the write-to-write operation can be solved.

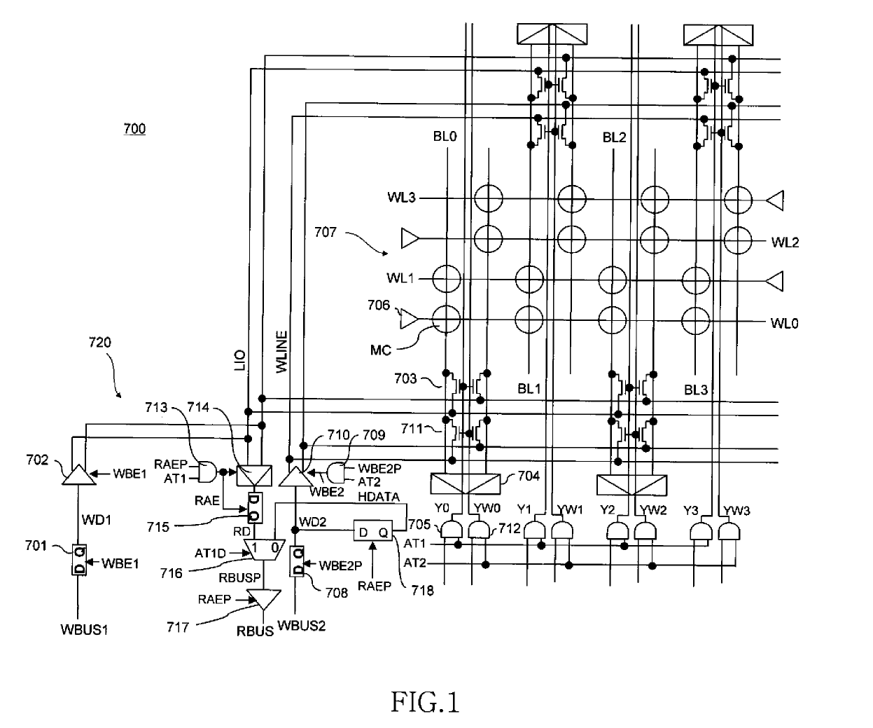

FIG. 1 is a circuit diagram showing a configuration of principal parts of a semiconductor memory device 700 according to the first embodiment.

As shown in FIG. 1, the semiconductor memory device 700 according to the first embodiment includes a phase-change memory cell array 707 that includes the word lines WL0, WL1, . . . , the bit line pairs BL0, BL1, . . . , and the memory cells MC arranged at intersections of the word lines with the bit lines. Sense amplifiers 704 are connected to each of the bit line pairs BL0, BL1, . . . . Each of the sense amplifiers 704 is connected via a corresponding column switch 703 to the I/O line LIO and via a corresponding column switch 711 to the data line WLINE for write. Column select signals Y0, Y1, . . . serving as outputs of column select drivers 705 are supplied to the respective column switches 703 and any one of the switches is turned on during the read operation or the write operation. Meanwhile, column select signals YW0, YW1, . . . for write serving as outputs of column select drivers 712 for write are supplied to the respective column switches 711 and any one of the switches is turned on during the write operation.

The I/O line LID is a wiring for transmitting complementary read or write data and connected to an input/output circuit 720. The data line WLINE for write is a wiring for transmitting complementary write data and connected to the input/output circuit 720. The input/output circuit 720 includes a write buffer 702 that supplies write data WD1 supplied to the I/O line LID through a write bus WBUS1, a write buffer 710 that supplies write data WD2 supplied through a write bus WBUS2 to the data line WLINE for write, and a read amplifier 714 that supplies the read data RD supplied to the read bus RBUS through the I/O line LID.

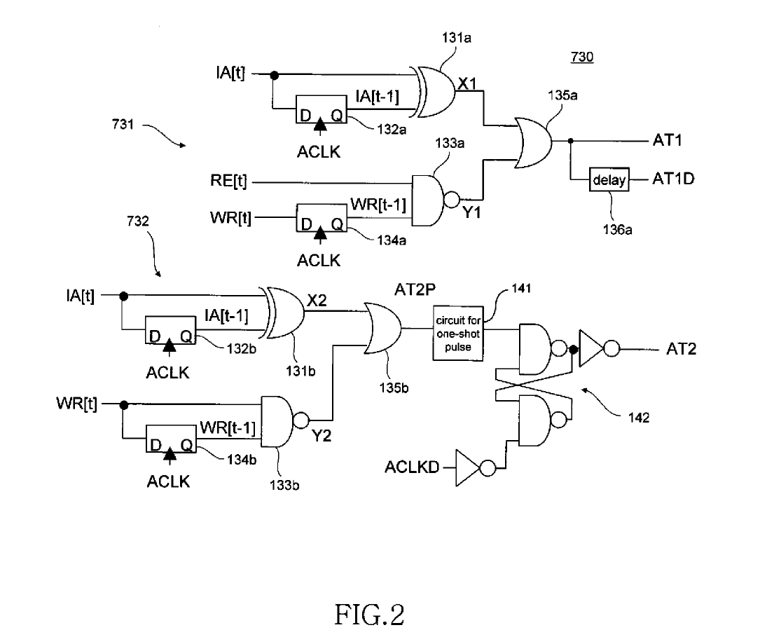

The input/output circuit 720 further includes a register 718 that temporarily holds the write data WD2 and a multiplexer 716 that selects either the output of the read amplifier 714 or the output of the register 718. The selection of the multiplexer 716 is controlled by an output of a detection circuit 730 shown in FIG. 2.

FIG. 2 is a circuit diagram showing the detection circuit 730 for generating an address transition detection signal AT.

As shown in FIG. 2, the detection circuit 730 includes a circuit part 731 for generating an address transition detection signal AT1 and a circuit part 732 for generating an address transition detection signal AT2. A current selected address IA[t], a current read-state flag RE[t], and a current write-state flag WR[t] are supplied to the detection circuit 730. The “state flag” means a signal that becomes “H” when a corresponding cycle is in a corresponding state and becomes “L” in other cases.

In the circuit part 731, the current selected address IA[t] is supplied to an EXOR gate 131a as it is and also supplied to a DQ latch 132a. The DQ latch 132a is a circuit that latches and then outputs the current selected address IA[t] in synchronization with an internal clock corresponding to an internal clock one cycle after the current cycle. The output is thus IA[t−1] indicating the selected address one cycle before the current cycle. Detailed descriptions thereof are as follows. When the DQ latch transmits data from D to Q during a period when the internal clock is H and latches the data at Q during a period when the internal clock is L, that is, when the DQ latch is a gate with a latching function, the internal clock supplied to the DQ latch is an internal clock earlier than the internal clock that outputs the selected address IA[t] by the period during which the internal clock is H. Thus, the data one cycle before the current cycle can be placed in the current cycle while preventing data penetration. When the DQ latch is a so-called DQ flip-flop, in which the gate with a latching function is connected in a master-slave manner, the internal clock supplied to the DQ latch can be a clock that is the same as the internal clock that outputs the selected address IA[t] and the data one cycle before the current cycle can be placed easily in the current cycle. IA[t−1] indicating the selected address one cycle before the current cycle is supplied to the EXOR gate 131a. Accordingly, when the same selected address is inputted twice consecutively, the EXOR gate 131a sets an output X1 to L. In other cases, the output X1 is maintained at high level.

The circuit part 732 also has the same circuit configuration. Therefore, when the same selected address is inputted twice consecutively, an EXOR gate 131b sets an output X2 to L. In other cases, the output X2 is maintained at high level.

In the circuit part 731, the current read-state flag RE[t] is supplied to a NAND gate 133a as it is, and the current write-state flag WR[t] is supplied to a DQ latch 134a. The DQ latch 134a performs the same operation as the DQ latch 132a and is a circuit that latches the current write-state flag WR[t] in synchronization with an internal clock corresponding to the internal clock one cycle after the current cycle. The output of the DQ latch 134a is thus a write-state flag WR[t−1] one cycle before the current cycle. The write-state flag WR[t−1] one cycle before the current cycle is supplied to the NAND gate 133a. Thus, when the write operation and the read operation are successively requested (that is, a write-to-read operation), the NAND gate 133a sets an output Y1 to L. In other cases, the output Y1 is maintained at high level.

Meanwhile, in the circuit part 732, the current write-state flag WR[t] is inputted to an end of a NAND gate 133b. An output Y2 thus becomes L when the write operation is successively requested twice (that is, a write-to-write operation). In other cases, the output Y2 is maintained at high level.

The outputs X1 and Y1 in the circuit part 731 are supplied to an OR gate 135a. Thus, only when the same selected address is inputted during the write-to-read operation, a logical level of the address transition detection signal AT1 becomes L. In other cases, the address transition detection signal AT1 is maintained at high level.

The address transition detection signal AT1 is supplied to a delay circuit 136a. An output of the delay circuit 136a becomes a delay address transition detection signal AT1D. The delay address transition detection signal AT1D is obtained by delaying the address transition detection signal AT1 to adjust timing.

The outputs X2 and Y2 in the circuit part 732 are supplied to an OR gate 135b. Thus, only when the same selected address is inputted during the write-to-write operation, a logical level of the output AT2P becomes L. In other cases, the output AT2P is maintained at high level.

The output AT2P is supplied via a one-shot pulse generating circuit 141 to an SR-FF 142. The SR-FF 142 is a circuit that is set by an output of the one-shot pulse generating circuit 141 and reset by a clock ACLKD. The clock ACLKD is a signal obtained by delaying an array control clock ACLK by a pre-write operation time d.

With reference to FIG. 1, there is described a write cycle and a read cycle when AT1=“H”, AT2=“H”, that is, in a normal case.

The write cycle is described first. In the write cycle, pre-write data is written in the write bus WBUS1, fetched into a hold circuit 701 at an activation timing of a signal WBE1, and supplied by the write buffer 702 to the I/O line LIO. The pre-write data is then supplied via the column switch 703 selected by the column select driver 705 to the bit line pair BL0. The bit line pair BL0 is driven by the sense amplifier 704 to write in memory cells MC selected by a word driver 706. When write in the memory cells MC is completed, the write data is written in the write bus WBUS2, fetched into a hold circuit 708 at an activation timing of a signal WBE2, and supplied by the write buffer 710 to the data line WLINE for write. The write data is then supplied via the column switch 711 selected by the column select driver 712 to the bit line pair BL0. The bit line pair BL0 is driven by the sense amplifier 704 to write again in the memory cells MC selected by the word driver 706.

The read cycle is described next. The read cycle is the same as the normal read operation. That is, the column switch 703 is selected by the column select driver 705 and the read data held by the sense amplifier 704 is read to the I/O line LIO. The read data is amplified by the read amplifier 714 at the activation timing of the activation signal RAEP and held by a hold circuit 715. Further, the read data is read through the multiplexer 716 to the signal line RBUSP and outputted to the read bus RBUS by a tri-state buffer 717. The hold circuit 718 temporarily holds write data WD2. The multiplexer 716 selects either an output of the read amplifier 714 or an output of the hold circuit 718. The selection of the multiplexer 716 is controlled by AT1D, which is an output of the detection circuit 730. The hold circuit 718 and the multiplexer 716 constitute a bypass circuit for supplying write data supplied through the write bus WBUS2 to the read bus RBUS.

The above operation is the operation when the address transition detection signals AT1=“H”, AT2=“H”, that is, in a normal case. As shown in FIG. 2, the address transition detection signal AT1 is generated by a detection circuit 731 and becomes “L” when the write-to-read operation is performed and the address does not transit. When AT1 becomes the L level, during the write-to-read operation for the same address, an operation is activated that with respect to the write operation and the read operation performed at the same time, the memory cell array 707 stops the read operation and performs only the write operation and a peripheral circuit returns data used for the write operation as it is as read data.

Further, the address transition detection signal AT2 is generated by a detection circuit 732, becomes “L” when the write-to-read operation is performed and the address does not transit, and is reset to “H” in the next cycle. When AT2 becomes the L level, during the write-to-write operation for the same address, an operation is activated that with respect to two simultaneous write operations, the earlier write operation is stopped and only the subsequent write operation is performed. The reason why reset by a signal ACLKD is required when generating the address transition detection signal AT2 will become clear from the following descriptions.

Operation timings in the write-to-write operation when addresses are different from each other and when the address are the same are described below with reference to a timing chart. For simplicity, descriptions are made by exemplifying an array control clock ACLK and a clock ACLKD obtained by delaying the array control clock ACLK by a pre-write operation time d.

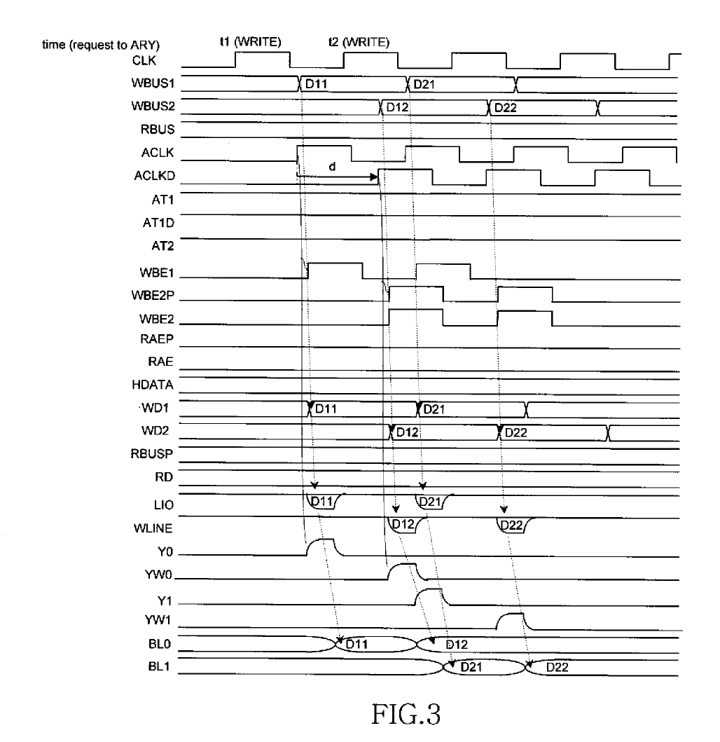

FIG. 3 is a timing diagram showing an operation timing when the write operation is successively requested for different addresses (write-to-write operation).

First, when the address corresponding to the bit line pair BL0 is specified and a write request is issued at the time t1, pre-write data D11 is supplied to the write bus WBUS1. The pre-write data D11 is then fetched into the hold circuit 701 by the signal WBE1 in synchronization with the array control clock ACLK and supplied to the I/O line LIO by the write buffer 702. Thereafter, the activation of the column select signal Y0 supplies the pre-write data D11 to the bit line pair BL0. Write data D12 is then supplied to the write bus WBUS2 with a delay of the pre-write operation time d. The write data D12 is fetched into the hold circuit 708 by a signal WBE2P in synchronization with the clock ACLKD delayed with respect to the array control clock ACLK by the pre-write operation timed and supplied to the data line WLINE for write by the write buffer 710. Thereafter, the activation of the column select signal YW0 supplies the write data D12 to the bit line pair BL0. In this way, pre-write and write are performed in this order upon predetermined memory cells connected to the bit line pair BL0.

Meanwhile, when the address corresponding to the bit line pair BL1 is specified and a write request is issued at the time t2, pre-write data D21 is supplied to the write bus WBUS1. The pre-write data D21 is then fetched into the hold circuit 701 by the signal WBE1 in synchronization with the array control clock ACLK and supplied to the I/O line LIO by the write buffer 702. Thereafter, the activation of the column select signal Y1 supplies the pre-write data D21 to the bit line pair BL1. Write data D22 is then supplied to the write bus WBUS2 with a delay of the pre-write operation time d. The write data D22 is fetched into the hold circuit 708 by the signal WBE2P in synchronization with the clock ACLKD delayed with respect to the array control clock ACLK by the pre-write operation time d and supplied to the data line WLINE for write by the write buffer 710. The activation of the column select signal YW1 supplies the write data D22 to the bit line pair BL1. In this way, pre-write and write are performed in this order upon predetermined memory cells connected to the bit line pair BL1.

The write operation for the data D12 requested at the time t1 and the pre-write operation for the data D21 requested at the time t2 are performed at the same time. Because the signal paths are separated perfectly as shown in FIG. 3, any data collision does not occur.

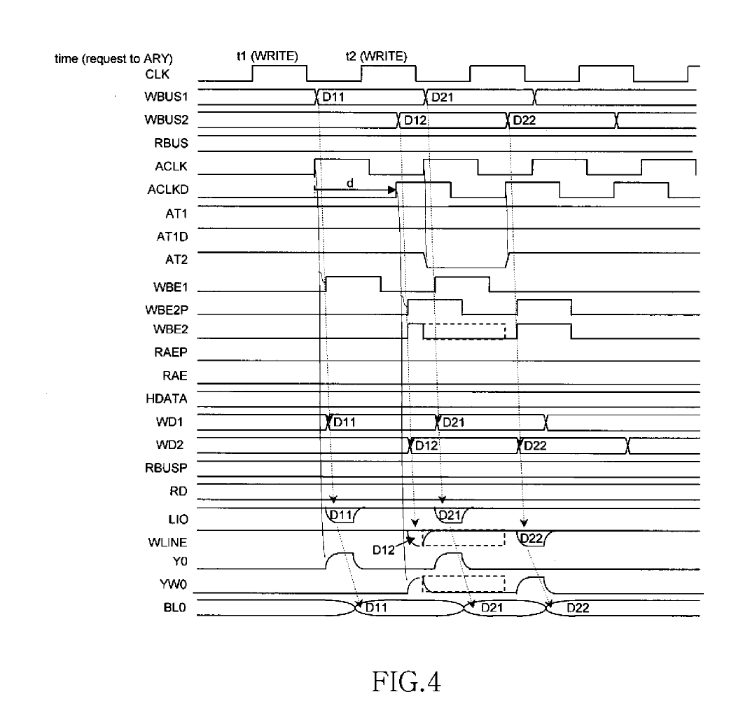

FIG. 4 is a timing diagram showing an operation timing when the write operation is successively requested for the same address (write-to-write operation).

First, when the address corresponding to the bit line pair BL0 is specified and a write request is issued at the time t1, the pre-write data D11 is supplied to the write bus WBUS1. The pre-write data D11 is then fetched into the hold circuit 701 by the signal WBE1 in synchronization with the array control clock ACLK and supplied to the I/O line LIO by the write buffer 702. Thereafter, the activation of the column select signal Y0 supplies the pre-write data D11 to the bit line pair BL0. The write data D12 is then supplied to the write bus WBUS2 with a delay of the pre-write operation time d. The write data D12 is fetched into the hold circuit 708 by the signal WBE2P in synchronization with the clock ACLKD delayed with respect to the array control clock ACLK by the pre-write operation time d and supplied to the data line WLINE for write by the write buffer 710. Because the address corresponding to the bit line pair BL0 is specified and a write request is issued also at the time t2, the operation in the next cycle interrupts during the write described above.

That is, when the address corresponding to the bit line pair BL0 is specified and a write request is issued at the time t2, pre-write data 021 is supplied to the write bus WBUS1. The pre-write data D21 is then fetched into the hold circuit 701 by the signal WBE1 in synchronization with the array control clock ACLK and supplied to the I/O line LIO by the write buffer 702. At this time, the write data D12 in the write cycle requested at the time t1 is being written in the data line WLINE for write. However, because the data D12 is to be overwritten by the pre-write data D21, it does not need to be written. Writing the write data D12 is stopped by the address transition detection signal AT2 and instead the pre-write data D21 is written in the I/O line LIO. Also in the subsequent activation operation of the column select signal, the activation of the column select signal YW0 is inhibited by using the address transition detection signal AT2 and the column select signal Y0 is activated instead. In this way, a collision of different write data on the bit line pair BL0 is avoided.

Next, the write data D22 is written in the write bus WBUS2 with a delay of the time d and fetched into the hold circuit 708 by the signal WBE2P in synchronization with the clock ACLKD. The held write data D22 is then supplied to the data line WLINE for write. However, when the address transition detection signal AT2 is caused to be in synchronization with only the array control clock ACLK, the address transition detection signal AT2 that becomes the L level is superimposed over the signal WBE2P at an H level at the time t2, which affects write in the data line WLINE for write. The address transition detection signal AT2 is thus reset using the clock ACLKD. Write in the data line WLINE for write is performed by the signal WBE2P and write in the bit line pair BL0 is performed by the column select signal YW0 in synchronization with the clock ACLKD.

As described above, in the write-to-write operation, the operations for different addresses and the operations for the same address can be performed without any data collision.

Next, there is described a write-to-write-to-read operation for the same address, which is the most complicated operation.

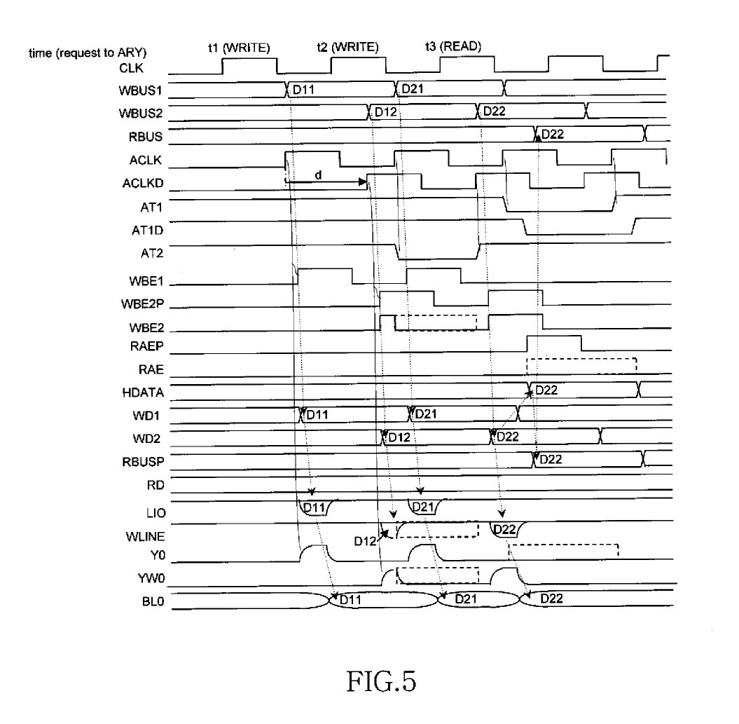

FIG. 5 is a timing diagram showing the write-to-write-to-read operation for the same address.

First, when the address corresponding to the bit line pair BL0 is specified and a write request is issued at the time t1, the pre-write data D11 is supplied to the write bus WBUS1. The pre-write data D11 is then fetched into the hold circuit 701 by the signal WBE1 in synchronization with the array control clock ACLK and supplied to the I/O line LID by the write buffer 702. Thereafter, the activation of the column select signal Y0 supplies the pre-write data D11 to the bit line pair BL0. The write data D12 is then supplied to the write bus WBUS2 with a delay of the pre-write operation time d. The write data D12 is fetched into the hold circuit 708 by the signal WBE2P in synchronization with the clock ACLKD delayed with respect to the array control clock ACLK by the pre-write operation time d and supplied to the data line WLINE for write by the write buffer 710. Because the address corresponding to the bit line pair BL0 is specified and the write request is issued also at the time t2 in this example, the operation in the next cycle interrupts during the write described above.

That is, when the address corresponding to the bit line pair BL0 is specified and a write request is issued at the time t2, the pre-write data D21 is supplied to the write bus WBUS1. The pre-write data D21 is then fetched into the hold circuit 701 by the signal WBE1 in synchronization with the array control clock ACLK and supplied to the I/O line LIO by the write buffer 702. At this time, the write data D12 in the write cycle requested at the time t1 is being written in the data line WLINE for write. However, because the data D12 is to be overwritten by the pre-write data D21, it does not need to be written. Writing the write data D12 is stopped by the address transition detection signal AT2 and instead the pre-write data D21 is written in the I/O line LIO. Also in the subsequent activation operation of the column select signal, the activation of the column select signal YW0 is inhibited by using the address transition detection signal AT2 and the column select signal Y0 is activated instead.

The write data D22 is then written in the write bus WBUS2 with a delay of the time d and fetched into the hold circuit 708 by the signal WBE2P in synchronization with the clock ACLKD. In response to the address transition detection signal AT=“H”, the write data D22 is supplied to the data line WLINE for write and written in the bit line pair BL0 by the column select signal YW0.

Further, when the address corresponding to the bit line pair BL0 is specified and a read request is issued at the time t3, the column select signal Y0 is usually caused to rise in synchronization with the array control clock ACLK and data is read from the bit line pair BL0. Because the write data D22 is being written currently, the address transition detection signal AT1=“L”. The column select signal Y0 does not rise accordingly and only the write operation of the write data D22 continues in the bit line pair BL0. The activation signal RAEP then rises and read data is usually fetched into the hold circuit 715. As the address transition detection signal AT1=“L”, however, the read amplifier 714 and the hold circuit 715 are not operated. A signal on the signal line HDATA is selected instead by the multiplexer 716 and outputted to the signal line RBUSP. The signal is further outputted to the read bus RBUS by the tri-state buffer 717.

As described above, according to the first embodiment, the write-to-write operation and the write-to-read operation can be performed correctly without rate-controlling the cycle time. Because the write operation is delayed by the pre-write operation in the first embodiment, note that operations become difficult with respect to the spec tDPL accordingly.

While the write in the write bus WBUS2 is delayed with respect to the write in the write bus WBUS1 in the first embodiment, these writes can be performed at the same time. When the data on the write bus WBUS2 is held for one cycle, the data can be fetched even though delayed by the time d.

A second embodiment of the present invention is described next.

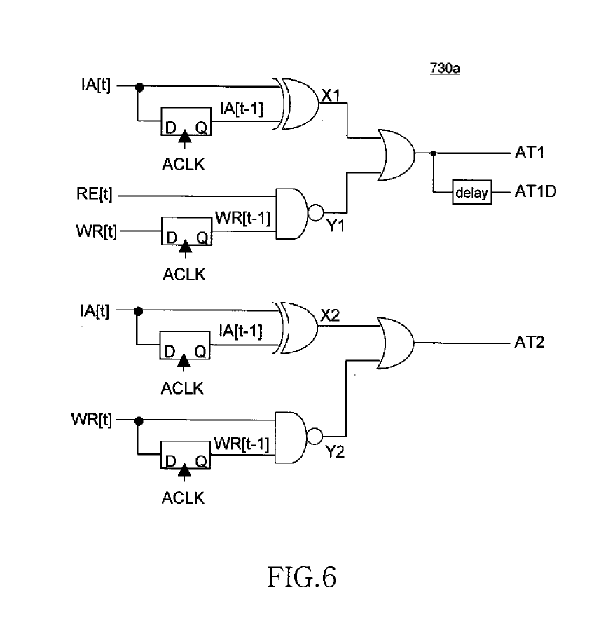

While the first embodiment performs the write operation promptly after the pre-write operation in the write cycle, the second embodiment performs the write operation and the pre-write operation in synchronization with the clock. Because the clock ACLKD estimating the pre-write operation time does not exist, the address transition detection signal AT2 for the write-to-write operation is generated by a detection circuit 730a shown in FIG. 6. The detection circuit 730a shown in FIG. 6 has a circuit configuration obtained by omitting SR-FF from the detection circuit 730 shown in FIG. 2. The circuit part that generates the address transition detection signal AT1 for the write-to-read operation is unchanged.

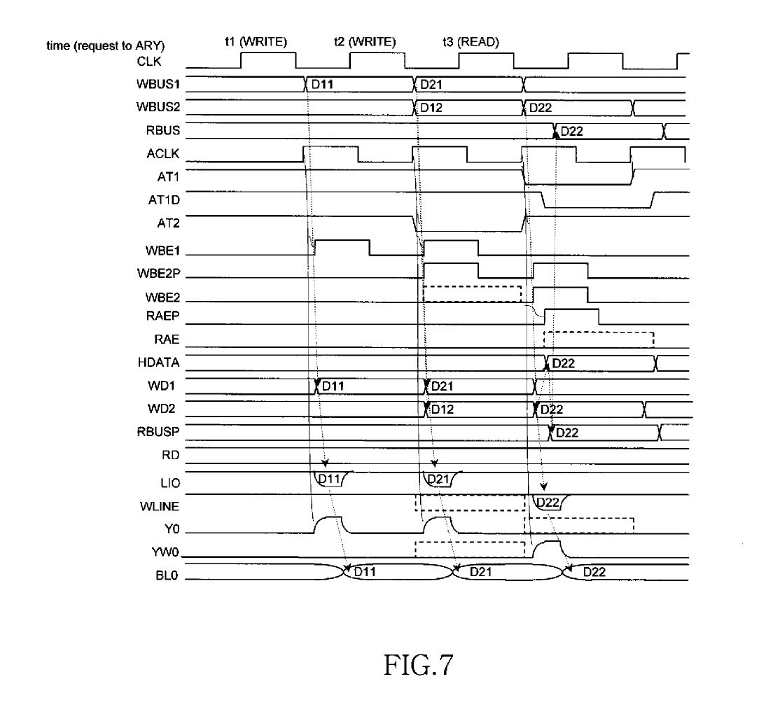

FIG. 7 is a timing diagram showing the write-to-write-to-read operation for the same address.

First, when the address corresponding to the bit line pair BL0 is specified and a write request is issued at the time t1, the pre-write data D11 is supplied to the write bus WBUS1. The pre-write data D11 is then fetched into the hold circuit 701 by the signal WBE1 in synchronization with the array control clock ACLK and supplied to the I/O line LIO by the write buffer 702. Thereafter, the activation of the column select signal Y0 supplies the pre-write data D11 to the bit line pair BL0. The write data D12 is then fetched into the hold circuit 708 by the signal WBE2P in synchronization with the time t2. While write in the data line WLINE for write is tried to be performed by the signal WBE2P in synchronization with the array control clock ACLK at the time t2, the signal WBE2 does not rise at all because the address transition detection signal AT=“L” and thus the write in the data line WLINE for write is not performed. The column select signal YW0 does not rise either.

When the address corresponding to the bit line pair BL0 is specified and a write request is issued at the time t2, the pre-write data D21 is supplied to the write bus WBUS1.

The pre-write data D21 is then fetched into the hold circuit 701 by the signal WBE1 in synchronization with the array control clock ACLK and supplied to the I/O line LIO by the write buffer 702. At this time, the write cycle at the time t1 when the operations are overlapped stops because AT2=“L”.

Accordingly, any data collision does not occur. While the operation being performed is made to stop in the first embodiment, the second embodiment does not perform the operation at all, which also suppresses the consumption current.

The write data D22 is then written in the write bus WBUS2 in synchronization with the time t3 and fetched into the hold circuit 708 by the signal WBE2P in synchronization with the array control clock ACLK at the time t3. In response to the address transition detection signal AT=“H”, the write data D22 is supplied to the data line WLINE for write and written in the bit line pair BL0 by the column select signal YW0.

Further, when the address corresponding to the bit line pair BL0 is specified and a read request is issued at the time t3, the column select signal Y0 is usually caused to rise in synchronization with the array control clock ACLK and data is read from the bit line pair BL0. Because the write data D22 is being written currently, however, the address transition detection signal AT1=“L”. The column select signal Y0 does not rise and only the write operation of the write data D22 continues in the bit line pair BL0. The activation signal RAEP then rises and read data is usually fetched into the hold circuit 715. As the address transition detection signal AT1=“L”, however, the read amplifier 714 and the hold circuit 715 are not operated. A signal on the signal line HDATA is selected instead by the multiplexer 716 and outputted to the signal line RBUSP. The signal is further outputted to the read bus RBUS by the tri-state buffer 717.

As described above, according to the second embodiment, the write-to-write operation and the write-to-read operation can be performed without rate-controlling the cycle time and without generating any data collision. Because the write operation is delayed by one cycle in the second embodiment, note that a latency of one cycle is required for tDPL.

While the write in the write bus WBUS2 is delayed with respect to the write in the write bus WBUS1 in the second embodiment, this process is essential in the second embodiment. When the data on the write bus WBUS2 and the data on the write bus WBUS1 are supplied at the same time, either write needs to be delayed by one cycle by a shift register.

A third embodiment of the present invention is described next.

According to recent DRAMs, a predetermined latency can be added to the period from when a write command is inputted to when the write operation upon an array is started. For example, according to DDR DRAMs, DQS starts to be inputted in the current cycle, data is fetched in synchronization with DQS in the next cycle, and the data is provided in synchronization with CLK in the cycle after the next cycle. Two cycles of the latency are thus provided. When a calculation is completed within the two cycles and the write operation is performed in the regular latency, the spec tDPL(tWR) is not violated. The third embodiment provides an example applying the configuration described in the second embodiment one cycle earlier. “Earlier” means that, for the pre-write operation and the write operation in response to an issuance of a write request, the pre-write operation is performed during a write latency period and the write operation is performed after the write latency, i.e., at a regular position. That is, it appears that the pre-write operation in response to the write request is hidden. Because the write operation in response to the write request is performed at a regular position, problems of a latency of the spec tDPL(tWR) are solved.

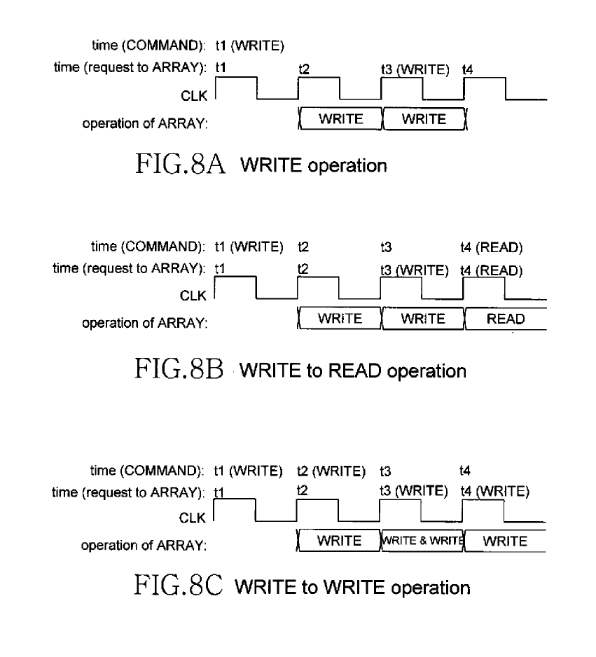

FIGS. 8A, 8B, and 8C are explanatory diagrams of operation timings in the third embodiment, where FIG. 8A shows a single write operation, FIG. 8B shows a write-to-read operation, and FIG. 8C shows a write-to-write operation. Because the data of the preceding write cannot be received externally in the third embodiment, assume that the data is determined in advance before the write operation.

In the write operation shown in FIG. 8A, with respect to a write command issued at the time t1, the regular write request upon the array is started at the time t3. Actually, pre-write is performed at the time t2 and write is performed at the time t3.

In the write-to-read operation shown in FIG. 8B, with respect to a write command issued at the time t1, the pre-write is performed at the time t2 and the write is performed at the time t3. A read command is then issued at the time t4 and the read operation is performed.

In the write-to-write operation shown in FIG. 8C, with respect to a write command issued at the time t1, the pre-write is performed at the time t2 and the write is performed at the time t3. With respect to a write command issued at the time t2, the pre-write is performed at the time t3 and the write is performed at the time t4. Only the write operation is performed at the time t2, two write operations are performed at the time t3 at the same time, and only the write operation is performed at the time t4.

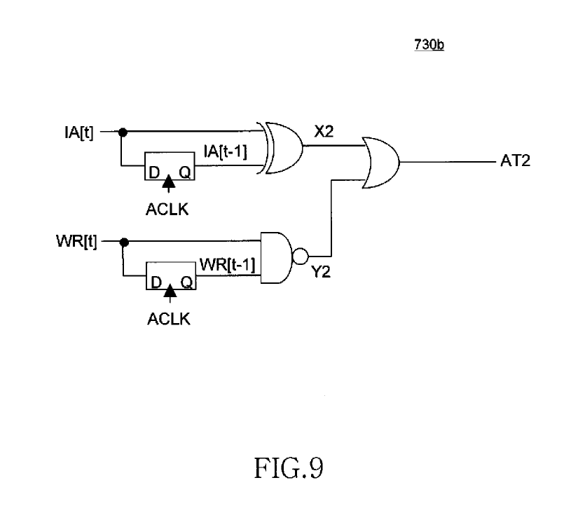

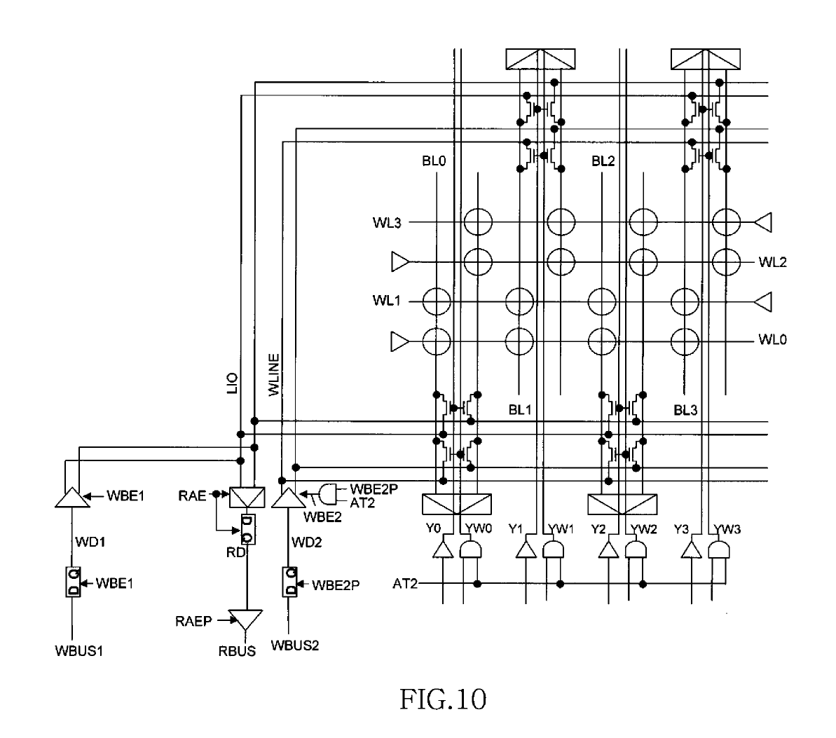

According to the third embodiment, while the operations do not overlap in the write-to-read operation, the operations overlap only in the write-to-write operation. A detection circuit 730b shown in FIG. 9 needs to be used as the circuit that generates address transition detection signal AT in the third embodiment. The detection circuit 730b shown in FIG. 9 has a configuration obtained by omitting the circuit that generates the address transition detection signal AT1 from the detection circuit 730a shown in FIG. 6. That is, it is sufficient to generate only the address transition detection signal AT2 for the write-to-write operation. A circuit configuration obtained by deleting the circuit that handles the write-to-read from the configuration shown in FIG. 1, such as the circuit configuration shown in FIG. 10 is provided. That is, only measures for the write-to-write operation will suffice, and it is important that data paths for two kinds of write operations are separated from each other.

A fourth embodiment of the present invention is described next.

The fourth embodiment relates to a multi-bit PRAM capable of storing binary or more information in a memory cell. The fourth embodiment is obtained by reconfiguring the first embodiment for a PRAM. Data is usually written in PRAM memory cells by applying current pulses to the memory device as follows.

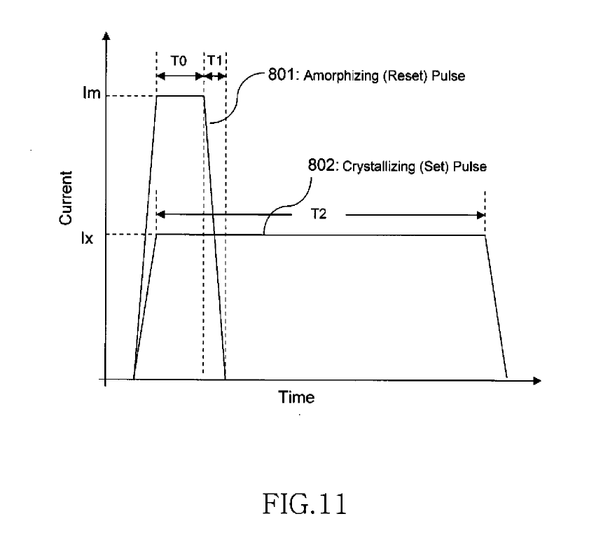

As shown in FIG. 11, to shift to an amorphous state (a state of high resistance and high threshold), a reset pulse 801 that is a short pulse of a large current is applied. The reset pulse 801 is set to have a current Im so as to apply sufficient power to melt a crystal. The current Im continues to be applied for a melt time TO and, when the crystal is melted, is caused to fall within a short fall time T1. The melted phase change material is thus cooled rapidly and a uniform amorphous state is provided. On the other hand, to shift to a crystalline state (a state of low resistance and low threshold), a set pulse 802 that is a long pulse of a smaller current is applied. The set pulse 802 continues to apply a current Ix that is sufficient for crystallization but does not melt the material for a crystallization time T2 to crystallize the material. These processes can control the memory device to be in the amorphous state or in the crystalline state. Precise adjustment of the pulses enables more precise control of crystal property.

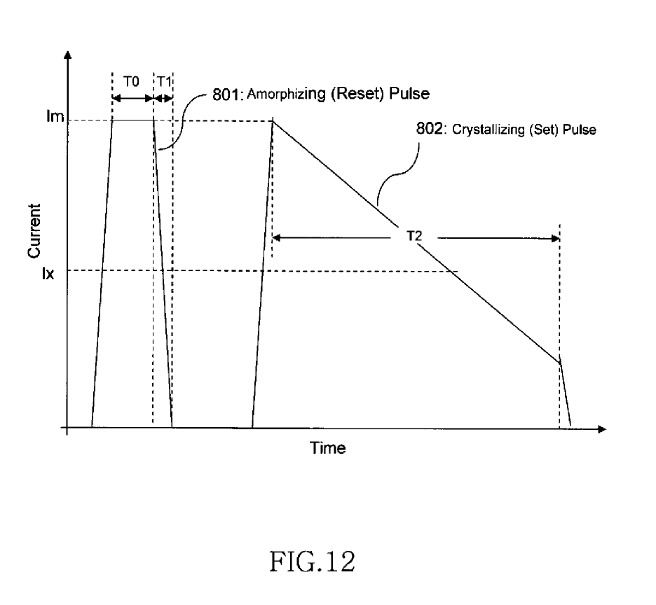

For example, as shown in FIG. 12, the device is once amorphized by the reset pulse 801 regardless of the logical level to be written. The set pulse 802 is then set to have a current value around the melting current Im and reduced gradually to a current value lower than the crystallizing current Ix. By controlling the time T2, the degree of crystallization can be adjusted.

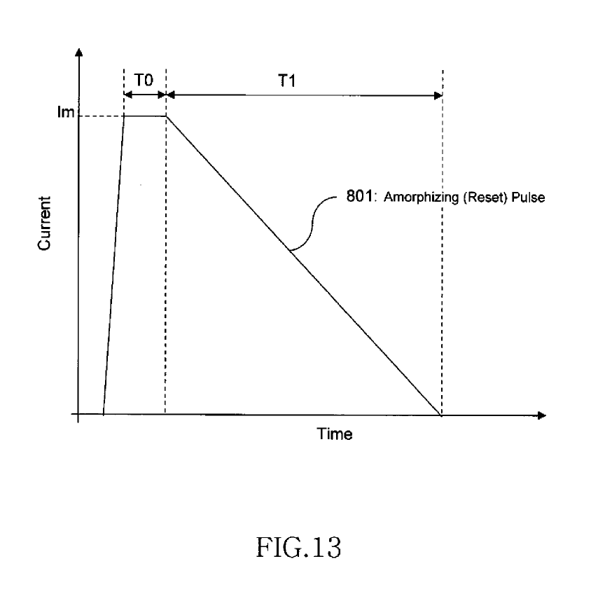

As shown in FIG. 13, only the reset pulse 801 is used and its fall time T1 is adjusted. As a result, the degree of crystallization is adjusted. In this case, as T1 is shortened, the amorphous state is provided. As T1 is extended, the degree of crystallization (the ratio of crystalline region to the entire amorphous region) is increased. A multi-bit device can be realized accordingly.

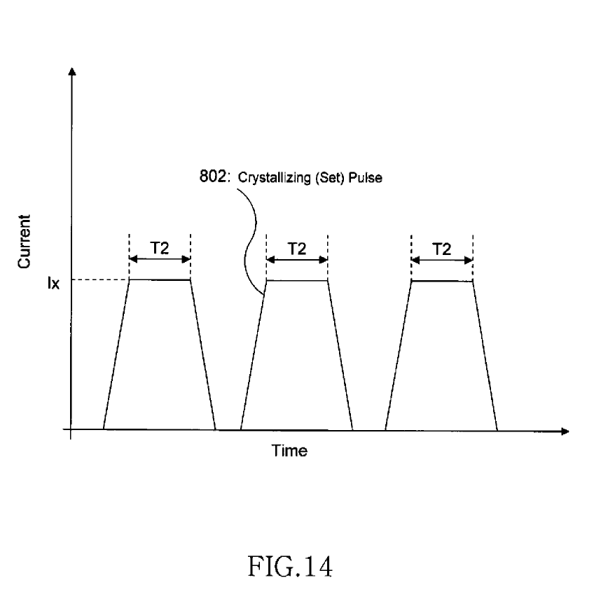

As shown in FIG. 14, a pulse width T2 of the set pulse 802 is set to be shorter than a pulse width enabling perfect crystallization and a plurality of shortened ones are applied. As a result, the degree of crystallization can be adjusted and the multi-bit device can be realized. Although not shown, the device is desirably amorphized once by the reset pulse regardless of the logical level to be written.

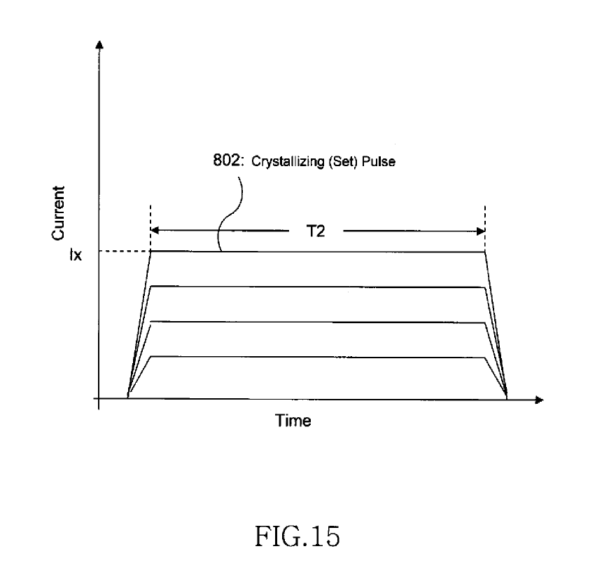

As shown in FIG. 15, the degree of crystallization can be adjusted and the multi-bit device can be realized by controlling the current value of the set pulse 802. Although not shown, the device is desirably amorphized once by the reset pulse regardless of the logical level to be written.

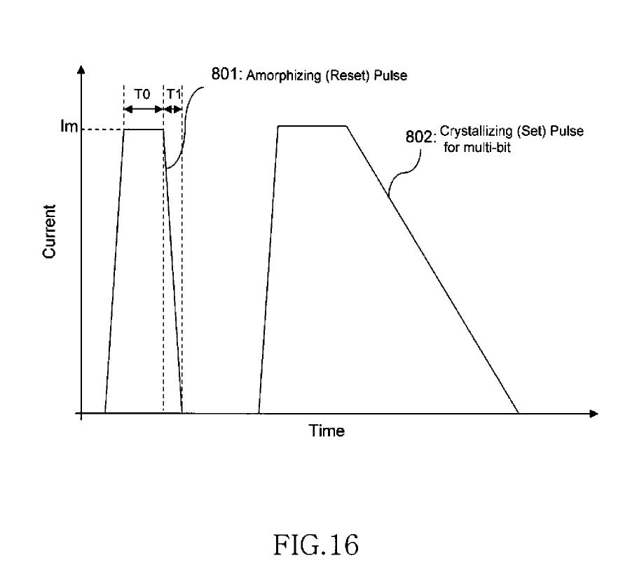

As shown in FIG. 16, the device is amorphized by the reset pulse 801 regardless of the logical level to be written and multi-bit data is then set using the adjusted set pulse 802 for adjusting thresholds. The multi-bit data can be stored accurately regardless of the prior state.

Thus, when the first embodiment is used to control the reset pulse 801 in the pre-write operation and the set pulse 802 in the subsequent write operation according to the methods shown in FIGS. 12 to 16, the multi-bit (including binary) PRAM can be probably configured without rate-controlling the cycle time. As the PRAM's write operation takes longer time than DRAMs, PRAMs are currently preferable “when tCK is large” or “when the cycle time of the array is larger than tCK because of a prefetch mechanism”. When the write operation in a PRAM can be performed at the same speed as that of a DRAM, the PRAM can be processed by the same manner as DRAMs.

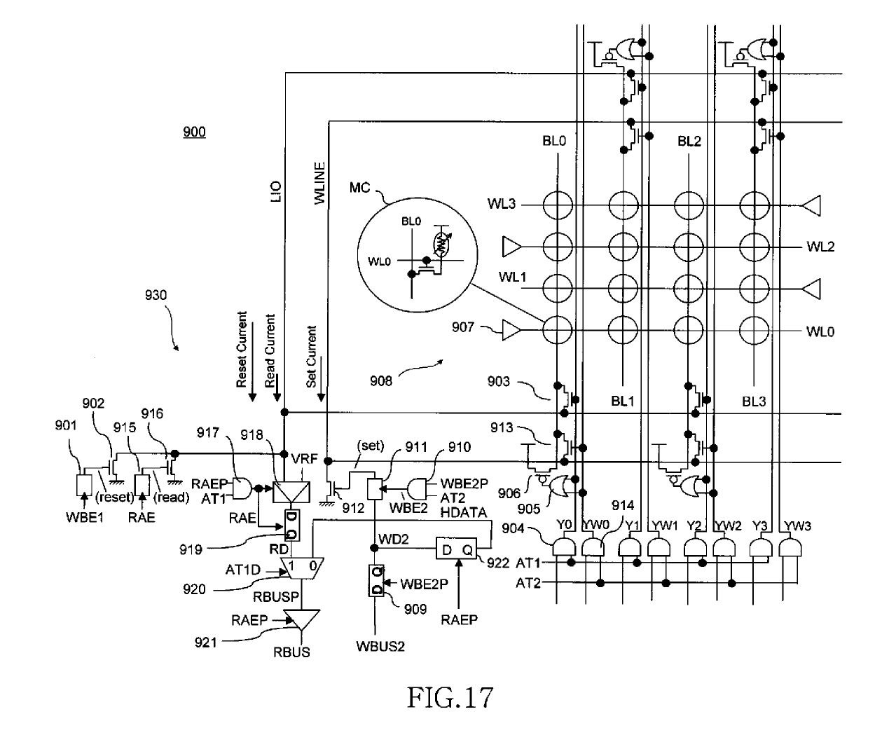

FIG. 17 is a circuit diagram showing a configuration of principal parts of a semiconductor memory device 900 according to the fourth embodiment. The semiconductor memory device 900 according to the fourth embodiment is a PRAM.

As shown in FIG. 17, the semiconductor memory device 900 according to the fourth embodiment includes a memory cell array 908 that includes the word lines WL0, WL1, . . . , the bit lines BL0, BL1, . . . , and the memory cells MC arranged at intersections of the word lines with the bit lines. Each of the bit line BL0, BL1, . . . is connected via a corresponding column switch 903 to the I/O line LIO and via a corresponding column switch 913 to a data line WLINE for write. The column select signals Y0, Y1, . . . serving as outputs of column select drivers 904 are supplied to the respective column switches 903 and any one of the switches is turned on during the read operation or the write operation. Column select signals YW0, YW1, . . . for write serving as outputs of column select drivers 914 for write are supplied to the respective column switches 913 and any one of the switches is turned on during the write operation.

The I/O line LIO is a single wiring for flowing a read current or a reset current and connected to an input/output circuit 930. The data line WLINE for write is a single wiring for flowing a set current and connected to the input/output circuit 930.

The input/output circuit 930 further includes a set pulse generator 912 that flows a predetermined set current to the data line WLINE for write based on write data WD supplied through the write bus WBUS and a read amplifier 918 that generates the read data RD based on a read current flowing in the I/O line LIO. The input/output circuit 930 further includes a register 922 that temporarily holds the write data WD and a multiplexer 920 that selects either an output of the read amplifier 918 or an output of the register 922.

As shown in FIG. 17, the memory cell MC is a PRAM cell formed of a pass gate PG and a phase change device PC. One end of the phase change device PC is fixed at high potential and the other end is connected to the pass gate PG. The pass gate PG is controlled by the word line WL and connects the bit line BL to the phase change device PC.

A reset pulse generator 902 that generates reset pulses is formed of an NMOS and controlled by a pre-write control signal WBE1 through a pulse shaper 901. The set pulse generator 912 is also formed of an NMOS and controlled by a write control signal WBE2P through a pulse shaper 911. Circuit configurations of the set pulse generator 912 and the pulse shaper 911 need to be changed depending on multi-bit recording methods. For example, a plurality of the set pulse generators 912 can be prepared and be selected by the pulse shaper 911. By controlling the pulse shaper 911, agate level of the set pulse generator 912 can be controlled.

A read current generator 916 generates a read current through a pulse shaper 915 not so as exceed a threshold of the phase change device PC. A potential of the I/O line LIO that varies depending on the read current is amplified by the read amplifier 918 that sets a potential VRF as the reference potential and latched into a hold circuit 919. A plurality of the read amplifiers 918 are provided for one I/O line LIO and thus multi-bit data is read. Note that the reference potentials VRF are different from each other.

A pre-charge circuit 906 is connected to the bit line BL. The pre-charge circuit 906 fixes the bit line BL at high potential so that the current does not flow in the phase change device PC when the word line WL is selected and the column select signal is not activated. Its control is performed by an OR gate 905. Because other configurations of the fourth embodiment are substantially identical to those of the first embodiment, duplicate descriptions thereof will be omitted.

As described above, the fourth embodiment can provide a multi-bit PRAM without any data collision because the reset pulse 801 can be controlled in the pre-write operation and the set pulse 802 can be controlled in the subsequent write operation. Also in the second and third embodiments, the reset pulse 801 can be controlled in the pre-write operation and the set pulse 802 can be controlled in the subsequent write operation.

It is apparent that the present invention is not limited to the above embodiments, but may be modified and changed without departing from the scope and spirit of the invention.

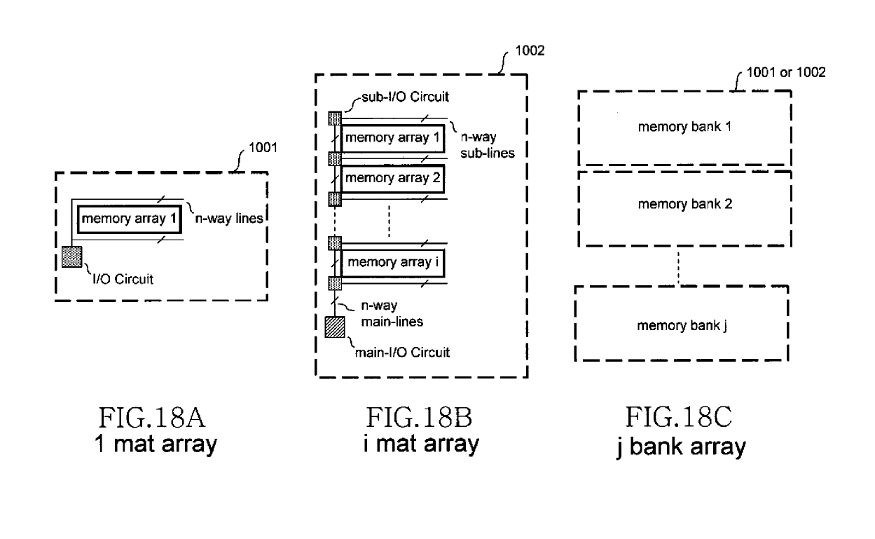

For example, data lines that connect the input/output circuit to the memory array in the above embodiments can be ones with a hierarchical configuration. Any number of hierarchies can be used in the configuration. The present invention can be applied to a one mat array configuration 1001 shown in FIG. 18A as described above. Even in a case of a multiple mat array configuration 1002 with a hierarchical data line configuration used for arrays of normal memory devices as shown in FIG. 18B, a sub input/output circuit is connected via a sub data line to a memory array and a main input/output circuit is connected via a main data line, the sub input/output circuit, and the sub data line to the memory array. Accordingly, the present invention can be applied in both cases of the sub input/output circuit and the main input/output circuit. Needless to mention, as shown in FIG. 18C, banks that can be operated independently can be provided.

What is claimed is:

1. A semiconductor memory device comprising:
a memory cell array including a plurality of word lines, a plurality of bit lines, a plurality of phase change memory cells arranged at intersections of the word lines with the bit lines, a plurality of sense amplifiers connected to corresponding bit lines, and a first column switch and a second column switch assigned to each of the sense amplifiers;
a first data line and a second data line connected through the first column switches and the second column switches to the sense amplifiers, respectively; and
an input/output circuit that supplies a pre-write data through the first data line to a selected phase change memory cell and then supplies a write data through the second data line to the selected phase change memory cell in response to a write request.

2. The semiconductor memory device as claimed in claim 1, further comprising:
a first write bus supplying the pre-write data to the input/output circuit;
a second write bus supplying the write data to the input/output circuit; and
a read bus supplied a read data from the input/output circuit.

3. The semiconductor memory device as claimed in claim 2, wherein the read data is supplied from the memory cell array through the first data line to the input/output circuit.

4. The semiconductor memory device as claimed in claim 2, wherein the input/output circuit includes a bypass circuit that supplies the write data to the read bus.

5. The semiconductor memory device as claimed in claim 4, wherein
the input/output circuit further includes a first detection circuit for detecting matching between a write address that the write data is to be written to and a read address that the read data is to be read from, and
the bypass circuit supplies the write data to the read bus in response to matching being detected by the first detection circuit.

6. The semiconductor memory device as claimed in claim 1, wherein
the input/output circuit includes a second detection circuit for detecting matching between a first write address that the pre-write data is to be written through the first data line and a second write address that the write data is to be written through the second data line, and
a write operation of the write data through the second data line is stopped in response to matching being detected by the second detection circuit.

7. The semiconductor memory device as claimed in claim 1, wherein the first data line includes a single interconnection for applying either a reset current or a read current to the phase change memory cell, and the second data line includes a single interconnection for applying a set current to the phase change memory cell.

8. The semiconductor memory device as claimed in claim 1, wherein the first data line and the second data line have a hierarchy structure.

9. A control method of a semiconductor memory device including phase change memory cells, the control method comprising:
performing a pre-write operation upon a selected phase change memory cell corresponding to a write address including a row address and a column address in response to an issuance of a write request; and
performing a write operation upon the selected phase change memory cell that has been subjected to the pre-write operation according to a write data.

10. The control method of a semiconductor memory device as claimed in claim 9, wherein the pre-write operation is performed in synchronization with a first active edge of an internal clock, and the write operation is performed in synchronization with a second active edge subsequent to the first active edge of the internal clock.

11. The control method of a semiconductor memory device as claimed in claim 9, wherein the pre-write operation is performed during a write latency period.

12. The control method of a semiconductor memory device as claimed in claim 11, wherein the write operation is performed at a regular timing after the write latency period.

13. A device comprising:
a memory cell array including a plurality of word lines, a plurality of bit lines, a plurality of memory cells arranged at intersections of the word lines with the bit lines; a first and second drivers;
a first switch electrically connecting the first driver to selected one or ones of the bit lines, the selected one or ones of the bit lines being thereby supplied with a pre-write data from the first driver; and
a second switch electrically connecting the second driver to the selected one or ones of the bit lines, the selected one or ones of the bit lines being thereby supplied with a write data from the second driver.
